(19) United States
(12) Patent Application Publication
(10) Pub. No.: US 2009/0242022 A1
(43) Pub. Date: Oct. 1, 2009

(54) Solar Cell

(76) Inventor: Satoshi Yonezawa, Tochigi (JP)

Correspondence Address: ARENT FOX LLP, 1050 CONNECTICUT AVENUE, N.W., SUITE 400, WASHINGTON, DC, 20036, US

(21) Appl. No.: 12/091,862

(22) PCT Filed: Jul. 4, 2006
(86) PCT No.: PCT/JP2006/313261

§ 371 Date: Apr. 28, 2008

(30) Foreign Application Priority Data
Oct. 27, 2005 (JP) 2005-313389

(51) Int. Cl. H01L 31/00

(52) U.S. Cl. 136/256

(57) ABSTRACT

A flexible solar cell is achieved which has a high photoelectric conversion efficiency and no aged deterioration. A cell 10 (unit cell) is formed as a unit, comprising: a lower electrode layer 2 (Mo electrode layer) formed on a flexible mica sheet substrate 1 (substrate); a light absorber layer 3 (CIGS light absorber layer) which contains copper indium gallium selenide; a highly resistant buffer layer thin film 4 formed of InS, ZnS, CdS, or the like on the light absorber layer 3; and an upper electrode layer 5 (TCO) formed of ZuOAl or the like, and furthermore, a contact electrode section 6 for connecting between the upper electrode layer 5 and the lower electrode layer 2 is formed in order to connect a plurality of unit cells 10 in series. The contact electrode section 6 has a Cu/In ratio higher than that of the light absorber layer 3, and in other words, has less In contained therein to have a property of p+ (plus) type or a conductor relative to the light absorber layer 3 which is a p-type semiconductor.

### TECHNICAL FIELD

The present invention relates to a chalcopyrite solar cell which is a compound solar cell, and more specifically relates to a solar cell using a flexible substrate and having an electrode connecting an upper electrode and a lower electrode.

### BACKGROUND ART

Solar cells which receive light for converting it into an electrical energy are categorized into bulk solar cells and thin film solar cells depending on the thickness of semiconductor thereof. Between the two, the thin film solar cells have a semiconductor layer having a thickness of several tens μm to several μm or less, which are further categorized into Si thin film solar cells and compound thin film solar cells. The compound thin film solar cells include II-VI compound based solar cells and chalcopyrite based solar cells for example, which have been manufactured as several products already. Among them, chalcopyrite solar cells in the chalcopyrite based solar cells are also called CIGS (Cu(InGa)Se) thin film solar cells, CIGS solar cells, or I-III-VI compound solar cells, for the substances used therein.

The chalcopyrite solar cells include chalcopyrite compounds as a light absorber layer formed therein, and are characterized by high efficiency, no optical deterioration (aged deterioration), high radiation resistance, wide absorption wavelength range, high absorption coefficient, and the like, thereby have been studied for mass production.

A cross section structure of a general chalcopyrite solar cell is shown in FIG. 1. As shown in FIG. 1, the chalcopyrite solar cell is comprised of a lower electrode layer (Mo electrode layer) formed on a substrate of glass or the like, a light absorber layer (CIGS light absorber layer) which contains copper-indium-gallium, and selenide, a highly resistant buffer layer thin film which is formed of InS, ZnS, CdS, or the like on the light absorber layer thin film, and an upper electrode thin film (TCO) which is formed of ZnOAl or the like. When the substrate is formed of soda lime glass or the like, the chalcopyrite solar cell often includes an alkaline control layer which is mainly formed of SiO₂ or the like to control leaching of an alkali metal component in the substrate to the light absorber layer.

When light such as sun light is irradiated to the chalcopyrite solar cell, a pair of an electron (−) and a positive hole (+) is generated in the light absorber layer, and the electron (−) is collected to an n-type semiconductor and the positive hole (+) is collected to a p-type semiconductor respectively at a bonding surface between the p-type semiconductor and the n-type semiconductor, as a result of that an electromotive force is produced between the n-type semiconductor and the p-type semiconductor. A connection of a conductor wire with an electrode in the state allows a current to be drawn out to the outside.

Conventionally, in a general chalcopyrite solar cell, a glass substrate has been used as a material of its substrate. This is because a good adhesion property can be obtained between the substrate and an Mo electrode layer a lower electrode, the substrate surface is smooth, the substrate has a high strength against mechanical cutting such as mechanical scribing, and the like. On the contrary, a glass substrate has a low melting point, and it is difficult to set a high temperature for annealing in a gas phase selenidation step of the substrate, which resulting in a number of drawbacks including photoelectric conversion efficiency, an increased size of facility for manufacturing due to a large thickness and volume of the substrate, the inconvenience in handling of its product due to an increased weight of a module of the substrates, and the inapplicability of mass production such as roll-to-roll process due to little flexibility of the substrate.

In order to compensate for the drawbacks of a glass substrate, a chalcopyrite solar cell which uses a polymeric film substrate (see Patent Document 1), a chalcopyrite solar cell which uses a substrate comprised of a stainless steel substrate and two layers of SiO₂ or iron fluoride that sandwich the stainless steel substrate therebetween (see Patent Document 2), and a chalcopyrite solar cell which uses a substrate formed of alumina, mica, polyimide, molybdenum, tungsten, nickel, graphite, and stainless steel (see Patent Document 3) is disclosed.

Steps for manufacturing a chalcopyrite solar cell are shown in FIG. 2.

First, an Mo (molybdenum) electrode is deposited by sputtering as a lower electrode on a glass substrate formed of soda lime glass or the like.

Next, as shown in FIG. 2(a), the Mo electrode is removed by means of laser radiation or the like to divide up the Mo electrode (a first scribing).

After the first scribing, debris is washed out using water or the like, and then copper (Cu), indium (In), and gallium (Ga) are deposited by sputtering for forming a precursor. The resulting precursor is placed in a furnace for annealing in an atmosphere of H₂Se gas so that a chalcopyrite light absorber layer thin film is formed. The annealing step is usually called as a gas phase selenidation, or simply a selenidation.

Next, an n-type buffer layer formed of CdS, ZnO, InS, or the like is laminated on the light absorber layer. The buffer layer is formed by sputtering, CBD (chemical bath deposition), or the like as a general process. Next, as shown in FIG. 2(b), the buffer layer and the precursor are removed using laser radiation, a metal needle, or the like to divide up the buffer layer and the precursor (a second scribing). FIG. 3 shows a scribing using a metal needle.

Then, as shown in FIG. 2(c), a transparent conducting oxide (TCO) of ZnOAl or the like is formed by sputtering or the like as an upper electrode. Finally, as shown in FIG. 2(d), the upper electrodes (TCO), the buffer layer, and the precursor are divided using laser radiation, a metal needle, or the like (a third scribing) so as to complete a CIGS thin film solar cell.

The solar cell obtained in the manner described above is so-called a cell, but in an actual use, a plurality of cells are packaged and processed to form a module (panel). The cell is comprised of a plurality of unit cells which are connected in series in each of the scribing steps, and in the case of a thin film solar cell, the number of connected rows in series (the number of unit cells) can be changed to change the design of a voltage of the cells as may be needed. This is one of the advantages of a thin film solar cell.

The prior art of the second scribing is disclosed in Patent Document 4 and Patent Document 5 for example. In Patent Document 4, a technology is disclosed for scraping off a light absorber layer and a buffer layer by pressing and moving a metal needle (needle) which is tapered at the tip thereof against the layers under a predetermined pressure. In Patent Document 5, a technology is disclosed for removing and dividing a light absorber layer by laser radiation (Nd:YAG laser) which is oscillated by exciting Nd:YAG crystals using a continuous discharge lamp such as an arc lamp.

Patent Document 1: Japanese Patent Application Publication No. 5-259494

Patent Document 2: Japanese Patent Application Publication No. 2001-339081

Patent Document 3: Japanese Patent Application Publication No. 2000-58893

Patent Document 4: Japanese Patent Application Publication No. 2004-115356

Patent Document 5: Japanese Patent Application Publication No. 11-312815

Assuming a case where a chalcopyrite light absorber layer is applied to a flexible substrate, in order to form a contact section between a lower electrode and an upper electrode for connecting cells in series, the light absorber layer will be scribed using a laser beam radiation, instead of a mechanical scribing, due to the flexibility of the substrate, and then TCO will be deposited by sputtering to a groove formed by the scribing to form a TCO film on the wall surfaces of the groove.

FIG. 4 is an enlarged cross sectional view showing a simulation of a state in which a part of a light absorber layer is scribed using a conventional method and then TCO is formed as an upper electrode by sputtering on the part, and as clearly seen in FIG. 4, the upper electrode film is not sufficiently deposited on the wall surface of the groove formed by the scribing, and is thin there. The thin TCO part is considered to have a high resistance. Generally in a thin film solar cell, in order to achieve a high voltage by a single solar cell modules a large number of cells are formed in a monolithic circuit on a single substrate, but when connections between the solar cells have a high resistance, a conversion efficiency of the whole module is decreased.

Also, the thin connections between the unit cells are easily broken by an external force and aged deterioration, which results in a reduced reliability.

A thicker transparent upper electrode can compensate the thickness at the connections between unit cells to some degree, but since TCO is not completely transparent, the thicker transparent upper electrode reduces the light amount which reaches a light absorber layer, thereby a light energy conversion efficiency (a generation efficiency) is reduced.

Furthermore, in addition to the above described common problems, the strength control of scribing using a metal needle or a laser beam to remove only a light absorber layer is difficult, and a too strong scribing breaks a lower electrode (Mo electrode). A too weak scribing cannot completely remove a light absorber layer and leaves some which forms a layer having a high resistance, thereby causing a problem that a contact resistance between an upper transparent conducting oxide (TCO) and a lower Mo electrode is extremely increased.

Also the use of a metal needle requires replacing due to wear for example, which caused a problem that the maintenance is troublesome.

In addition, when a metal needle is used, there is a big problem in using flexible substrates described in Patent Documents 1 to 3. That is, when a substrate formed of a resin such as polyimide, a substrate formed of a natural mineral such as mica, or a graphite (carbon) substrate is used, a “scratching” by a metal needle causes the material of the substrate to wrinkle and tear, which disenables a scribing. Also, when a tungsten substrate, a nickel substrate, a graphite substrate, a stainless steel substrate or the like is used, the conductive substrate requires an insulation layer formed of SiO₂ or the like, but a scribing of the substrate also cuts the insulation layer, which does not allow a formation of a monolithic connection in series.

### DISCLOSURE OF THE INVENTION

In order to solve the above problems, a solar cell according to the present invention includes: a substrate having flexibility; a plurality of lower electrodes which is formed by dividing a conductive layer on the flexible substrate; a chalcopyrite light absorber layer which is formed on the plurality of lower electrodes and divided into plural parts; a plurality of upper electrodes which are formed by dividing a transparent conductive layer formed on the light absorber layer; and a contact electrode section which is formed by modifying a part of the light absorber layer to make the conductivity thereof higher than that of the light absorber layer so that unit cells each of which is comprised of the lower electrode layer, the light absorber layer, and the upper electrodes are connected in series.

A solar cell according to the present invention is basically configured to have lower electrodes, a light absorber layer, and upper electrodes laminated on a substrate as described above, but these layers are only the essential elements of a solar cell according to the present invention, and as may be needed, a buffer layer, an alkaline passivation film, an antireflection film, and the like may be interposed between the layers, and such solar cells are also within the scope of a solar cell of the present invention.

The contact electrode section is modified to have a Cu/In ratio higher than that of a light absorber layer, so as to have properties different from a p-type semiconductor and function as an electrode. When the lower electrodes are formed of molybdenum (Mo), the contact electrode section is modified resulting in an alloy which contains molybdenum.

Furthermore, the substrate having flexibility, a mica sheet substrate which contains mica is appropriate, and a structure having a middle layer which contains a ceramic material and a nitride-based binder layer between the mica sheet substrate and the lower electrodes is preferable.

With use of a substrate having flexibility, a solar cell of the present invention uses an electrode which is obtained by modifying a light absorber layer as an electrode for connecting a transparent conducting oxide layer and a lower electrode layer so that any breakage of the substrate can be prevented, and the inner electrical resistance of the connection in series can be reduced, thereby a highly reliable chalcopyrite solar cell can be obtained which has a high photoelectric conversion efficiency and no aged deterioration.

In addition, when a mica sheet substrate is used as the flexible substrate, a middle layer which contains a ceramic material may be provided between the mica sheet substrate and the lower electrodes to make a surface roughness of the substrate smooth like that of a glass substrate. The mica substrate contains potassium as an impurity which reduces a photoelectric conversion efficiency of the substrate, but a nitride-based binder layer may be provided to limit the diffusion of potassium to that of a glass substrate or less.

### BRIEF DESCRIPTION OF THE DRAWINGS

FIG. 1 is a cross sectional view showing a structure of a conventional chalcopyrite solar cell;

FIG. 2 is a view illustrating a series of steps for manufacturing a conventional chalcopyrite solar cell;

FIG. 3 is a view showing a scribing using a metal needle;

FIG. 4 is an enlarged cross sectional view showing a simulation of a state in which a part of a light absorber layer is scribed using a conventional method and then TCO is formed by sputtering on the part as an upper electrode;

FIG. 5(a) is a cross sectional view showing main sections of a solar cell (cell) according to the present invention, and FIG. 5(b) is a view separately illustrating unit cells which comprise a solar cell (cell) according to the present invention;

FIG. 6 is a view illustrating a method for manufacturing a chalcopyrite solar cell of the present invention;

FIG. 7 is a SEM picture of a light absorber layer and a surface of a contact electrode after laser radiation;

FIG. 8(a) is a graph showing a result of component analysis of a light absorber layer to which a laser contact forming step is not performed, and FIG. 8(b) is a graph showing a result of component analysis of a resulting laser contact section after a laser contact forming step;

FIG. 9(a) is a graph showing differences in carrier concentrations of a light absorber layer depending on a Cu/In ratio, and FIG. 9(b) is a graph showing changes in resistivity depending on a Cu/In ratio;

FIG. 10 is a SEM picture of a solar cell surface after a lamination of TCO; and

FIG. 11 is a SEM picture showing a cross section of a contact electrode and a light absorber layer.

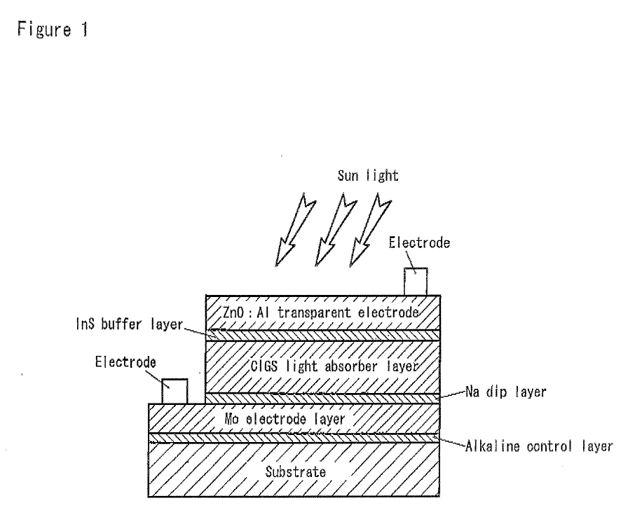

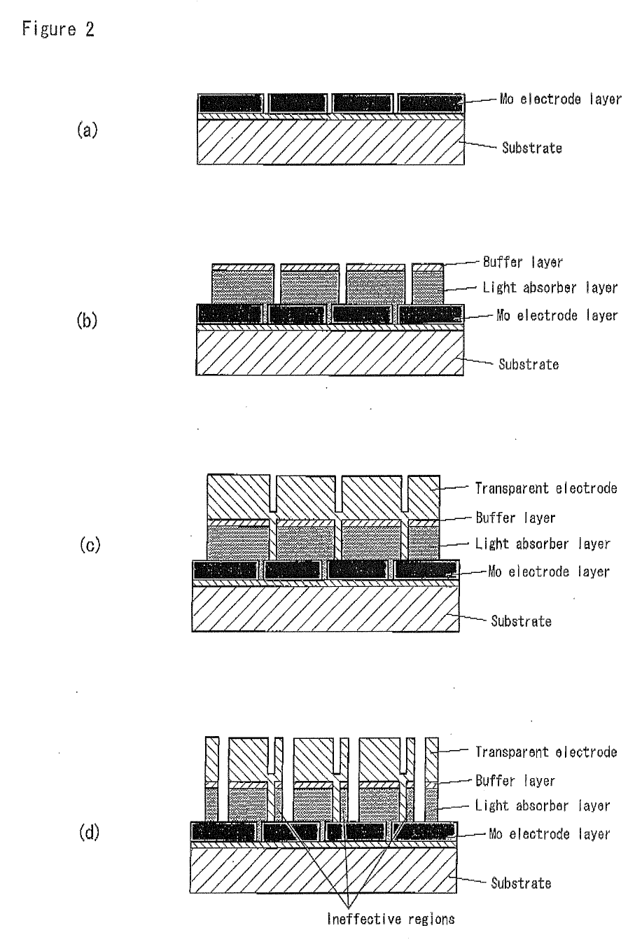

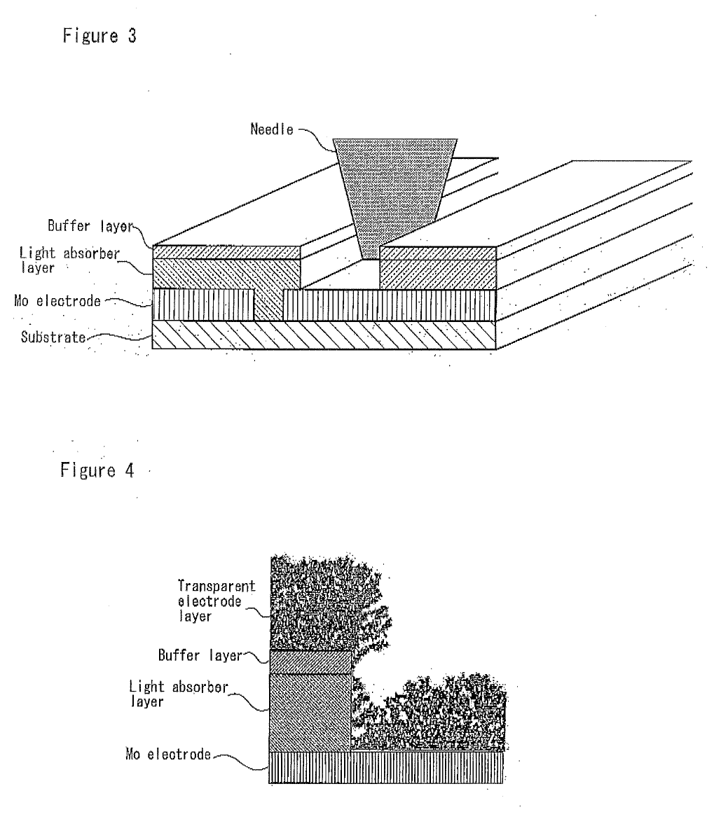

### BEST MODE FOR CARRYING OUT THE INVENTION

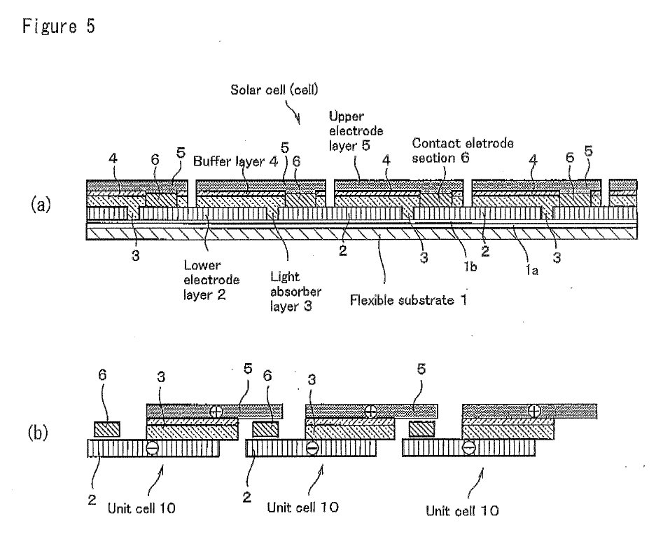

A chalcopyrite solar cell according to the present invention is shown in FIG. 5. FIG. 5(a) is a cross sectional view showing main sections of a solar cell (cell), and FIG. 5(b) is a view separately illustrating unit cells which comprise a solar cell (cell).

In the solar cell, a cell 10 (unit cell) is formed as a unit, comprising: a lower electrode layer 2 (Mo electrode layer) formed on a flexible substrate 1 (substrate); a light absorber layer 3 (CIGS light absorber layer) which contains copper-indium-gallium, and selenide; a highly resistant buffer layer thin film 4 formed of InS, ZnS, CdS, or the like on the light absorber layer 3; and an upper electrode layer 5 (TCO) formed of ZnOAl or the like, and furthermore, a contact electrode section 6 for connecting between the upper electrode layer 5 and the lower electrode layer 2 is formed in order to connect a plurality of unit cells 10 in series.

The contact electrode section 6 hasp as will be explained later, a Cu/In ratio higher than that of the light absorber layer 3, and in other words, has less In contained therein to have a property of p+ (plus) type or a conductor relative to the light absorber layer 3 which is a p-type semiconductor.

Also, in the present examples as the material of the flexible substrate 1, a mica sheet which contains mica is used for explanation. Mica is also called as “isinglass”, and is highly insulative to have an insulation resistance of 10¹² to 10¹⁶Ω, and also has a high heat resistance temperature of 800 degrees C. to 1000 degrees C., and moreover is highly resistant to acid, alkali and selenidation hydrogen (H₂Se) gas, light-weighted, and flexible.

The mica sheet substrate used in the present example can be obtained by mixing a ground mica with a resin and rolling or baking the resulting mixture. The mica sheet having a resin mixed therein has a lower heat resistance than that of a pure mica substrate, but still has a heat resistance temperature of the order of 600 degrees C. to 800 degrees C., and so is resistant to a temperature higher than a heat resistance temperature (melting temperature) of 500 degrees C. to 550 degrees C. of a soda lime glass substrate which is usually used as a substrate of a thin film solar cell.

By the way, it has been confirmed that a CIGS solar cell has a conversion efficiency which is enhanced when the CIGS solar cell is heat treated at a temperature of 600 degrees C. or more 700 degrees C. or less in a gas phase selenidation. The reason can be presumed as follows: at a temperature of around 500 degrees C., Ga is segregated on the lower electrode thin film side of a light absorber layer in an uncrystallized state which has a characteristic of a small range of band gap and a low current density, but a gas phase selenidation process of the solar cell at a temperature of 600 degrees C. or more 700 degrees C. or less causes the Ga to diffuse uniformly in a light absorber layer and eliminates the uncrystallized state, resulting in an expanded bandgap and an enhanced open circuit voltage (Voc).

On the mica sheet substrate 1 which is a flexible substrate, a middle layer 1a is provided. The middle layer 1a is provided to make a surface roughness of the flexible substrate smooth like that of a glass substrate, and in the present example, as a middle layer, a coating including titanium (Ti) of 39% by weight which is a ceramic material, oxygen (O) 28.8% by weight, silicon (Si) of 25.7% by weight, carbon (C) of 2.7% by weight, and aluminium (Al) of 1.6% by weight is applied on a mica sheet substrate.

The coating of a ceramic material enables an improvement of a shunt resistance between an upper electrode and a lower electrode, and a reduction of leak, which results in that a conversion efficiency is increased.

Between the flexible mica sheet substrate 1 and the lower electrodes 2 (Mo electrode), a binder layer 1b is further provided. The binder layer 1b prevents the diffusion of an impurity from the mica sheet substrate and also improves the adhesion between molybdenum or tungsten which is used in a back electrode thin film and the substrate 1 or the middle layer 1a. As a material of the binder layer 1b, a nitride system compound (nitride based compound) such as TiN or TaN is suitable.

The binder layer is formed by sputtering method, CVD method, or the like. The binder layer preferably has a thickness of 300 nm or more in order to limit the diffusion of potassium which is an impurity present in the mica substrate to that of any existing glass substrate or less.

As to the upper limit of the TiN thickness, no upper limit can be obtained din terms of a conversion efficiency, and a thickness of about 1000 Å is clearly enough to meet the performance. However, as the thickness of the binder layer is increased, the flexibility is reduced and the stress of the binder layer itself causes a detachment of the binder layer from the middle layer or the lower electrodes (Mo electrode). In addition, the manufacturing cost for sputtering is increased in proportion to the thickness. According to the experiments conducted by the inventors of the present invention, the detachment was often found with the thickness of 10000 Å (1 μm). Therefore, empirically, the upper limit of the binder layer thickness is desirably 8000 Å or less.

In the present example, a middle layer and a binder layer are provided between a flexible substrate and a lower electrode, but the middle layer may be omitted when a flexible substrate having a small surface roughness (roughness) is used. Alternatively, when a flexible substrate having a high adhesion with molybdenum, titanium and tungsten which are electrode materials, or a flexible substrate without any impurity which adversely affects a light absorber layer is used, the binder layer may be omitted.

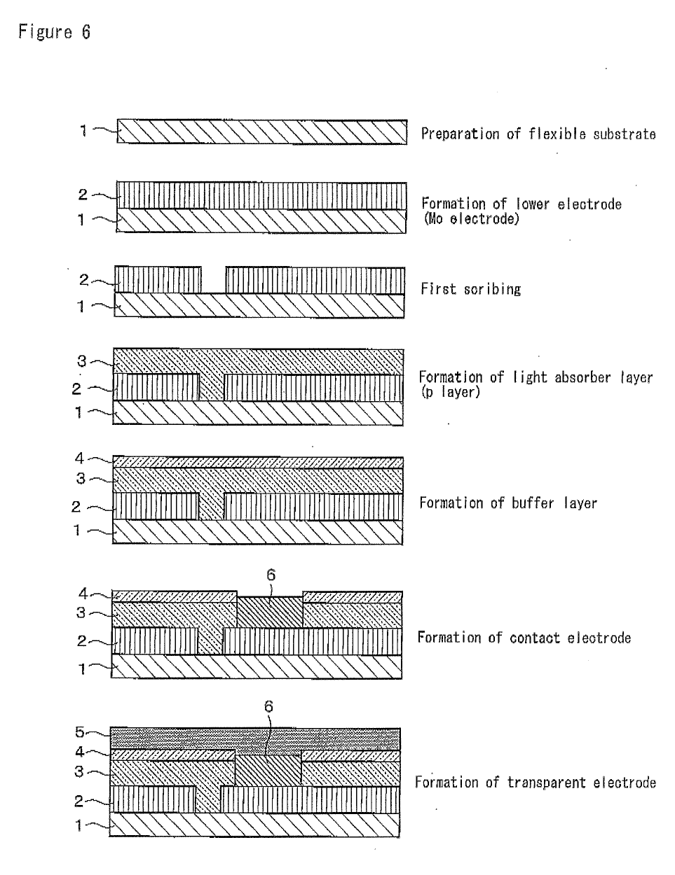

Next, a method for manufacturing a chalcopyrite solar cell of the present invention is shown in FIG. 6. First, an Mo (molybdenum) electrode is deposited by sputtering or the like as a lower electrode on a flexible substrate. In the present example, a mica sheet substrate having a middle layer and a binder layer on the flexible substrate will be used for explanation below.

Next, the Mo electrode is removed and divided up by laser radiation or the like (a first scribing).

The laser is desirably an excimer laser having a wavelength of 256 nm, or the third higher harmonics of YAG laser having a wavelength of 355 nm. The laser is also desirably processed to have a channel width within a range of about 80 to 100 nm, which secures insulation between adjacent Mo electrodes.

After the first scribing, copper (Cu), indium (In), and gallium (Ga) are deposited by sputtering deposition, or the like, to form a layer which is called as a precursor. The precursor is placed in a furnace for annealing in an atmosphere of H₂Se gas at a temperature of about 400 degrees C. to 600 degrees C. so as to attain a light absorber layer thin film. The annealing step is usually called as a gas phase selenidation, or simply a selenidation.

For the light absorber layer forming step, some technologies have been developed including an annealing after formation of Cu. In, Ga, and Se by deposition. In the present example, gas phase selenidation is used for explanation, but the present invention is not limited to any of a light absorber layer forming step.

Next, a buffer layer which is an n-type semiconductor such as CdS, ZnO, and InS is laminated on the light absorber layer. The buffer layer is generally formed in a dry process such as sputtering or a wet process such as CBD (chemical bath deposition). The buffer layer may be omitted due to an improvement of transparent conducting oxide which will be explained later.

Next, a laser is radiated to modify the light absorber layer and form a contact electrode section. The laser is also radiated on the buffer layer, but the buffer layer itself is much thinner than the light absorber layer, and so no effect of the presence/absence of the buffer layer has been found in the experiments conducted by the inventors of the present invention.

Then, a transparent conducting oxide (TCO) of ZnOAl or the like is formed by sputtering or the like as an upper electrode on the buffer layer and the contact electrode. Finally, the TCO, the buffer layer, and the precursor are removed and divided by laser radiation, a metal needle, or the like (a scribing for element separation).

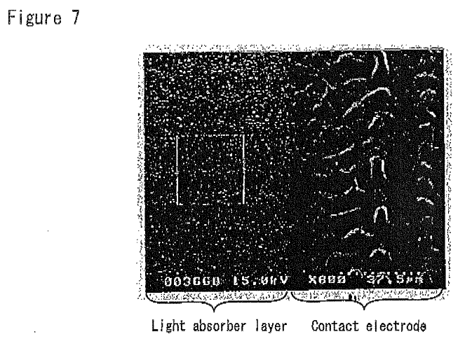

FIG. 7 shows a SEM picture of a light absorber layer and a surface of a contact electrode after laser radiation. As shown in FIG. 7, as compared to the light absorber layer which has grown into a particulate state, the contact electrode has a surface which was melt by the laser energy.

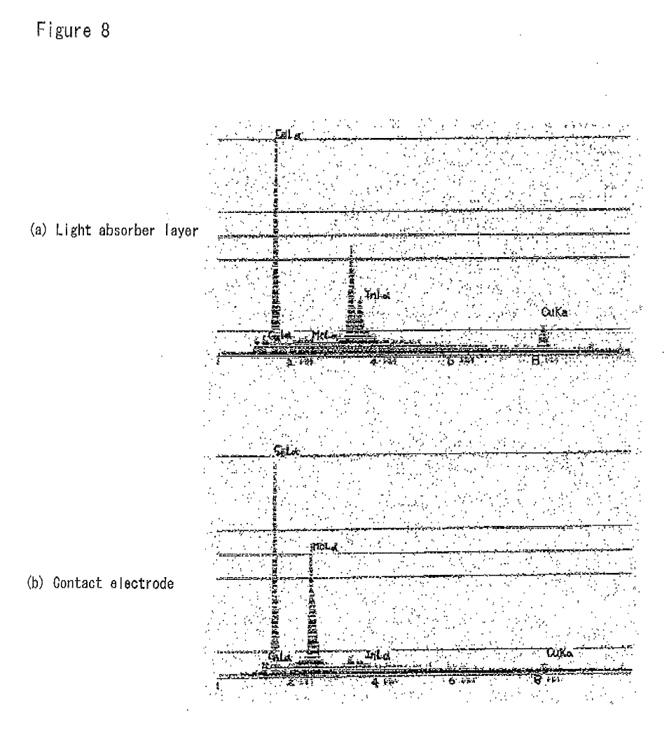

For more detailed analysis, with reference to FIG. 8, a contact electrode formed in the present invention will be examined below in comparison with a light absorber layer before laser radiation.

FIG. 8(a) shows a result of component analysis of a light absorber layer to which a laser contact forming step is not performed, and FIG. 8(b) shows a result of component analysis of a resulting laser contact section after a laser contact forming step. The analysis was conducted by EPMA (Electron Probe Micro-Analysis). EPMA is an analytical technique in which constituent elements of a substance are detected by radiating an accelerated electron beam on the substance and analyzing the spectrum of character X-rays which are generated when the electron beam is excited, so that the ratio of each constituent element (concentration) is analyzed.

FIG. 8 demonstrates that indium (In) is outstandingly decreased in the contact electrode as compared to the light absorber layer. The decrease rate was accurately calculated using an EPMA apparatus, and found to be 1/3.61. Similarly, by focusing upon copper (Cu), the decrease rate of copper (Cu) was calculated, and found to be 1/2.37. Thus, the above results show that laser radiation outstandingly decreases In, and as for a ratio. In is decreased much more than Cu.

The characteristics other than the above include that molybdenum (Mo) was detected which had been rarely detected in a light absorber layer. Reasons of the change will be considered below.

According to the simulation performed by the inventors, for examples when a laser beam having a wavelength of 355 n is radiated at a ratio of 0.1 J/cm², the surface temperature of a light absorber layer is raised to about 6,000 degrees C. Of course, the temperature on the internal (lower) side of the light absorber layer is lower than that, but the light absorber layer used in the present example has a thickness of 1 μm, thereby the internal of the light absorber layer is supposed to have al extremely high temperature, Now, indium has a melting point of 156 degrees C. and a boiling point of 2,000 degrees C., and copper has a melting point of 1,084 degrees C. and a boiling point of 2,595 degrees C. Thus, as compared to copper, it can be seen that the temperature of indium at deeper portions of the light absorber layer reaches the boiling point. Also, since molybdenum has a melting point of 2,610 degrees C., it can be seen that some molybdenum in the lower electrode is melted to be introduced in the light absorber layer.

First, a change in characteristics due to a change in ratios of copper and indium will be considered below.

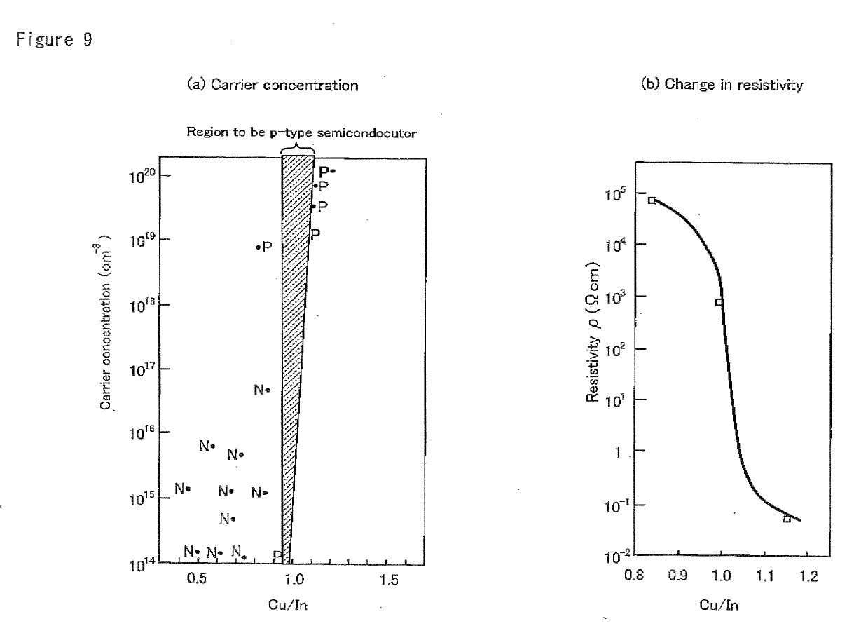

FIG. 9 shows a change in characteristics due to a change in Cu/In ratios. FIG. 9(a) shows differences in carrier concentrations of a light absorber layer depending on a Cu/In ratio, and FIG. 9(b) shows changes in resistivity depending on a Cu/In ratio.

As shown in FIG. 9(a), in use, a light absorber layer is required to have a controlled Cu/In ratio of about 0.95 to 0.98. As shown in FIG. 8, in a contact electrode after a contact electrode section forming step in which a laser is radiated, the Cu/In ratio calculated by using measured amounts of copper and indium is changed into values greater than 1. This shows that the contact electrode has changed to have a property of p+ (plus) type or a metal Now, focusing on FIG. 9(b)), as the Cu/In ratio is changed into values greater than 1, the resistivity is found to be rapidly decreased. Specifically, when the Cu/In ratio is within a range of 0.95 to 0.98, the resistivity is about 10⁴ Ωcm, while the Cu/In ratio is changed to 1.1, the resistivity is rapidly decreased to about 0.1 Ωcm.

Next, molybdenum which was melted to be introduced into the light absorber layer will be considered below.

Molybdenum is a metallic element belonging to group VI in the periodic table, and exhibits characteristics having a specific resistance of 5.4×10⁻⁶ Ωcm. When the light absorber layer melts and is recrystallized after pulling in molybdenum, the resistivity is decreased.

From the two reasons described above, the contact electrode can be considered to be changed to have a property of a p+ (plus) type or a metal, and has a resistance lower than that of the light absorber layer.

Next, a lamination of a transparent conducting oxide layer to a contact electrode section will be explained below.

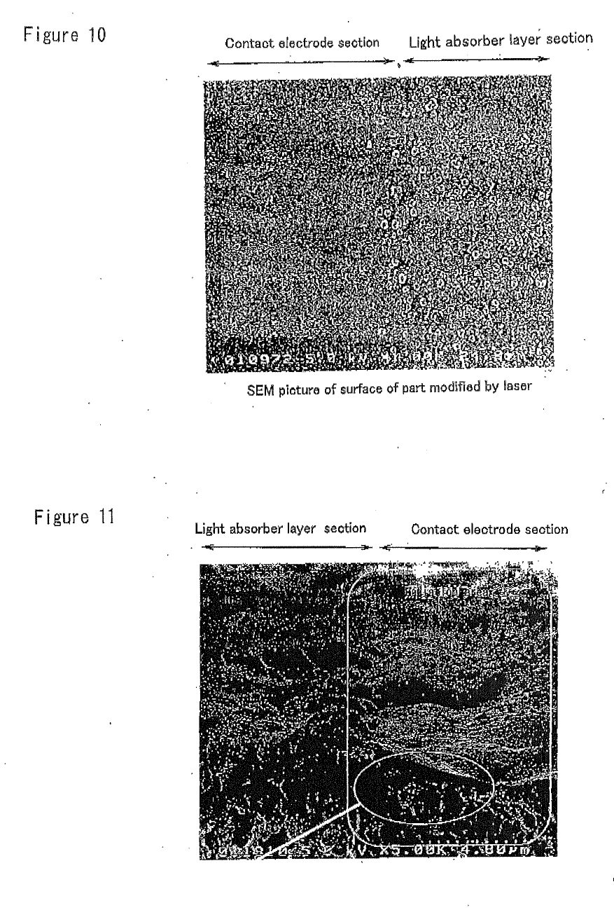

FIG. 10 shows a SEM picture of a solar cell surface after TCO lamination.

In a conventional scribing, it was difficult to conduct a scribing for removing a light absorber layer because the scribing breaks a flexible substrate. To the contrary, in the present invention shown in FIG. 10, the contact electrode enables a structure of a monolithic connection in series and there is no level difference which corresponds to a film thickness of the light absorber layer, thereby no defects in the transparent conducting oxide can be found.

In order to clearly show that the film thickness of the contact electrode has no outstanding change as compared to that of the light absorber layer. FIG. 11 shows a SEM picture showing a cross section of a contact electrode and a light absorber layer.

The contact electrode shown in FIG. 11 was radiated five times by a laser having a wavelength of 20 kHz, an output of 467 mW, and a pulse width of 35 ns. The number of radiations was set to be five in order to check the decrease in the film thickness of the contact electrode after laser radiations.

As shown in FIG. 11, even after five times of laser radiations, the film thickness of the contact electrode is still large.

As described above, in using a substrate material having flexibility, a contact electrode formed by modifying a light absorber layer in a contact electrode section forming step in which a laser is radiated is obtained, as the result of that any breakage of the substrate can be prevented, and an inner electrical resistance of a connection in series can be reduced, and a highly reliable chalcopyrite solar cell can be obtained which has a high photoelectric conversion efficiency and no aged deterioration.

1. A solar cell, comprising:
a substrate having flexibility;
a plurality of lower electrodes which is formed by dividing a conductive layer on the flexible substrate,
a chalcopyrite light absorber layer which is formed on the plurality of lower electrodes and divided into plural parts;
a plurality of upper electrodes which are formed by dividing a transparent conductive layer formed on the light absorber layer; and
a contact electrode section which is formed by modifying a part of the light absorber layer to make the conductivity thereof higher than that of the light absorber layer so that unit cells each of which is comprised of the lower electrode layer, the light absorber layer, and the upper electrodes are connected in series.

2. The solar cell according to claim 1, wherein
the upper electrodes are formed on the light absorber layer via a buffer layer.

3. The solar cell according to claim 1 or 2, wherein
the contact electrode section has a Cu/In ratio which is higher than that of the light absorber layer.

4. The solar cell according to claim 1, wherein
the contact electrode section is an alloy which contains molybdenum.

5. The solar cell according to any one of claims 1 to 4, wherein
the substrate having flexibility is a mica sheet substrate which contains mica, and
a middle layer which contains a ceramic material and a nitride-based binder layer are interposed between the mica sheet substrate and the lower electrodes.
